(19) United States
(12) Patent Application Publication
(10) Pub. No.: US 2021/0086407 A1
(43) Pub. Date: Mar. 25, 2021

(54) WAFER TILING METHOD TO FORM LARGE-AREA MOLD MASTER HAVING SUB-MICROMETER FEATURES

(71) Applicant: LEIA INC., Menlo Park, CA (US)

(72) Inventors: Zhen Peng, Menlo Park, CA (US); Sonny Vo, Menlo Park, CA (US); Emeline Soichi, Menlo Park, CA (US)

(21) Appl. No.: 17/112,941

(22) Filed: Dec. 4, 2020

Related U.S. Application Data
(63) Continuation of application No. PCT/US2018/067187, filed on Dec. 21, 2018.
(60) Provisional application No. 62/681,662, filed on Jun. 6, 2018.

(51) Int. Cl. B29C 33/38; B29C 33/42; B29C 33/56; G03F 7/00

(52) U.S. Cl. CPC B29C 33/3878; G03F 7/0002; B29C 33/56; B29C 33/424

(57) ABSTRACT

A method of forming a large-area nanoimprint mold master is provided. The method includes positioning a plurality of sub-master tiles on a rigid planar substrate. Each sub-master tile of the sub-master tile plurality has a nanoscale pattern and represents a subsection of the large-area nanoimprint mold master. The method further includes adhering the plurality of sub-master tiles to the rigid planar substrate. The positioning determines a distance between a nanoscale feature of the nanoscale pattern on each sub-master tile of a pair of adjacent sub-master tiles. The distance has microscale positioning tolerance. Also provided are a large-area nanoimprint mold master and a method of large-area nanoimprint lithography.

### CROSS-REFERENCE TO RELATED APPLICATIONS

This application is a continuation patent application of and claims the benefit of priority to International Application No. PCT/US2018/067187, filed Dec. 21, 2018, which claims priority from U.S. Provisional Patent Application Ser. No. 62/681,662, filed Jun. 6, 2018, the entire contents of which are herein incorporated by reference.

### STATEMENT REGARDING FEDERALLY SPONSORED RESEARCH OR DEVELOPMENT

N/A

### BACKGROUND

Electronic displays are a nearly ubiquitous medium for communicating information to users of a wide variety of devices and products. Among the most commonly found electronic displays are the cathode ray tube (CRT), plasma display panels (PDP), liquid crystal displays (LCD), electroluminescent displays (EL), organic light emitting diode (OLED) and active matrix OLEDs (AMOLED) displays, electrophoretic displays (EP) and various displays that employ electromechanical or electrofluidic light modulation (e.g., digital micromirror devices, electrowetting displays, etc.). Many of these modern displays require high precision manufacturing to fabricate various display structures and elements.

Imprint lithography and especially nanoimprint lithography is among a number of available fabrication techniques and methodologies that find utility in producing various structures and elements associated with modern electronic displays. In particular, nanoimprint lithography generally excels at providing sub-micrometer or nanoscale features having very high precision, while simultaneously being readily adaptable to mass production. For example, nanoimprint lithography may be used to create a stamp or mold master having nano-scale features by aggregating together or tiling wafers having nanoscale imprint patterns. The mold master may then be used in nanoimprint lithography to imprint the nanoimprint patterns onto a receiving substrate. Further, various high-volume fabrication methodologies including, but not limited to, role-to-role imprinting may be used in conjunction with nanoimprint lithography and the mold master to serve the needs of mass production. However, providing sub-micrometer or nanoscale feature precision over a large-area mold master may be problematic. In particular, maintain nanoscale precision across the large-area mold master may be hampered, in practice, if the nanoscale feature precision must extend beyond a boundary of the wafers, e.g., between nanoscale features on different wafers. As such, while large-scale manufacturing using imprint lithography and even nanoimprint lithography may have matured, these manufacturing processes are typically limited to micrometer or larger size features.

### BRIEF DESCRIPTION OF THE DRAWINGS

Various features of examples and embodiments in accordance with the principles described herein may be more readily understood with reference to the following detailed description taken in conjunction with the accompanying drawings, where like reference numerals designate like structural elements, and in which:

FIG. 1A illustrates a cross-sectional view of a large-area nanoimprint mold master in an example, according to an embodiment consistent with the principles described herein.

FIG. 1B illustrates a cross-sectional view of a large-area nanoimprint mold master in an example, according to another embodiment consistent with the principles described herein.

FIG. 2 illustrates cross-sectional view of a large-area nanoimprint mold master in an example, according to an embodiment consistent with the principles described herein.

FIG. 3A illustrates a cross-sectional view of a large-area nanoimprint mold master in an example, according to an embodiment consistent with the principles described herein.

FIG. 3B illustrates a cross-sectional view of a large-area nanoimprint mold master in an example, according to another embodiment consistent with the principles described herein.

FIG. 4 illustrates a plan view of a large-area nanoimprint mold master in an example, according to an embodiment consistent with the principles described herein.

FIG. 5 illustrates a flow chart of a method of forming a large-area nanoimprint mold master in an example, according to an embodiment consistent with the principles described herein.

FIG. 6A illustrates a cross-sectional view of using a large-area nanoimprint mold master to perform large-area nanoimprint lithography in an example, according to an embodiment consistent with the principles described herein.

FIG. 6B illustrates another cross-sectional view of using the large-area nanoimprint mold master of FIG. 6A in an example, according to an embodiment consistent with the principles described herein.

FIG. 6C illustrates another cross-sectional view of using the large-area nanoimprint mold master of FIG. 6A in an example, according to an embodiment consistent with the principles described herein.

FIG. 7 illustrates a flow chart of a method of large-area nanoimprint lithography, according to an embodiment consistent with the principles described herein.

Certain examples and embodiments have other features that are one of in addition to and in lieu of the features illustrated in the above-referenced figures. These and other features are detailed below with reference to the above-referenced figures.

### DETAILED DESCRIPTION

Examples and embodiments in accordance with the principles described herein combine high precision sub-micrometer patterning and large scale manufacturing to provide a large-area nanoimprint mold master. In particular, the large-area nanoimprint mold master may be formed by positioning a plurality of wafer tiles or sub-master tiles on a rigid planar substrate, each sub-master tile of the sub-master tile plurality having a nanoscale pattern and representing a subsection of the large-area nanoimprint mold master. The plurality of sub-master tiles may be adhered to the rigid planar substrate. The positioning determines a distance between a nanoscale feature of the nanoscale pattern on each sub-master tile of a pair of adjacent sub-master tiles. The distance has microscale positioning tolerance. According to various embodiments, fabrication of a large-area nanoimprint mold master having sub-micrometer (nanoscale) size features and its precise replication as an imprint stamp to enable high precision and low cost manufacturing of such structures (e.g., displays and solar panels) may be provided. Such a large-area nanoimprint mold master may be used to produce a large-scale display or other typically two-dimensional (2D) structure requiring sub-micrometer or nanoscale precision over a large-area substrate, according to various embodiments.

Herein, fabrication of a large-area nanoimprint mold master having sub-micrometer (nanoscale) size features and its precise replication as an imprint stamp to enable high precision and low cost manufacturing of such structures (e.g., displays and solar panels) may be provided. Such a large-area nanoimprint mold master may be used to produce a large-scale display or other typically two-dimensional (2D) structure requiring or at least benefiting from sub-micrometer or nanoscale precision over a large-area substrate. Combining high precision sub-micrometer patterning and large-scale manufacturing may considerably lower the technical and cost barrier for new applications such as displays including, but not limited to, diffractive light field displays, plasmonic sensors, and various metamaterials for clean energy, biological sensors, memory or storage disks, etc. to name a few.

As used herein, ‘micrometer scale’ or ‘micrometer scale’ refers to dimensions within a range of one micrometer (1 μm) to one thousand micrometers (1000 μm). Further as used herein, ‘sub-micrometer scale’ or ‘sub-micrometer scale’ may be used interchangeably and refer to dimensions less than 1 μm. As used herein, ‘nanometer scale’ or ‘nanoscale’ may be used interchangeably and refer to dimensions within a range of one millimeter (1 nm) to less than one thousand nanometers (1000 nm), i.e., less than one micrometer (<1 μm). As such, ‘sub-micrometer’ and ‘nanometer’ and their equivalents may also be used interchangeably. Further herein, “large-area” is defined as a structure that is generally more than two orders of magnitude larger than size of a sub-micrometer or nanoscale structure of the large-area nanoimprint mold master. For example, a large-area substrate may have a size that is on the order of meters-by-meters or feet-by-feet, while the nanoscale features are on the order of nanometers to micrometers in size, in some embodiments. Further, by definition herein a “wafer” or a “sub-master tile” having nanoscale features may have a maximum size that is less than about thirty centimeters (30 cm), e.g., lees than 30 cm×30 cm, while the large-area nanoimprint mold master or a large-area receiving substrate may be greater than about one meter (m), e.g., greater than 1 m×1 m.

As used herein, a ‘multiview backlight’ employs a guided-wave illumination technique based on light-emitting diodes that produce wide-angle multiview images in color from a thin planar transparent light guide. Such a multiview backlight system may comprise a backlight light guide and a plurality of light extraction features, or multibeam elements. The backlight light guide is configured to guide collimated light received from a grating collimator as guided collimated light. The plurality of multibeam elements are spaced apart from one another along a length of the light guide. A multibeam element of the plurality of multibeam elements is configured to scatter out from the light guide a portion of the guided light as a plurality of directional light beams having different principal angular directions corresponding to respective different view directions of a multiview display. As used herein, a ‘diffractive multibeam backlight’ employs diffraction grating elements as the multibeam elements.

Further, as used herein, the article ‘a’ is intended to have its ordinary meaning in the patent arts, namely ‘one or more’. For example, ‘a sub-master tile’ means one or more sub-master tiles and as such, ‘the sub-master tile’ means ‘the sub-master tile(s)’ herein. Also, any reference herein to ‘top’, ‘bottom’, ‘upper’, ‘lower’, ‘up’, ‘down’, ‘front’, back', ‘first’, ‘second’, ‘left’ or ‘right’ is not intended to be a limitation herein. Herein, the term ‘about’ when applied to a value generally means within the tolerance range of the equipment used to produce the value, or may mean plus or minus 10%, or plus or minus 5%, or plus or minus 1%, unless otherwise expressly specified. Further, the term ‘substantially’, as used herein, means a majority, or almost all, or all, or an amount within a range of about 51% to about 100%. Moreover, examples herein are intended to be illustrative only and are presented for discussion purposes and not by way of limitation.

In accordance with principles disclosed herein, a method of forming a large-area nanoimprint mold master is provided. The method comprises positioning a plurality of sub-master tiles on a rigid planar substrate. Each sub-master tile of the sub-master tile plurality has a nanoscale pattern and represents a subsection of the large-area nanoimprint mold master. The method further comprises adhering the plurality of sub-master tiles to the rigid planar substrate. The positioning determines a distance between a nanoscale feature of the nanoscale pattern on each sub-master tile of a pair of adjacent sub-master tiles. The distance may have a microscale positioning tolerance, according to some embodiments.

A large scale wafer master may be provided by fabricating multiple wafers with sub-micrometer patterns (e.g., using semiconductor fabrication methods on a semiconductor substrate), cutting each wafer into desired shape and dimension precisely, tiling the pieces together into desired large array and bonding them to a rigid large scale substrate such as a glass panel. Wafers with sub-micrometer patterns may be made by advanced lithography such as e-beam or a DUV (deep ultraviolet) stepper, in some embodiments.

Different patterns, including alignment marks for downstream processing, may be included in the tiling. The alignment marks allow compatibility with manufacturing techniques and methods, and different device patterns may allow flexibility in production while also maximizing material utilization options.

There are described herein, by way of example and not limitation, at least three different aspects of the method of forming the large-area nanoimprint mold master. Each different aspect is directed to a different positioning accuracy regime. In the first aspect, the positioning accuracy is generally greater than ten micrometers (10 μm). In the second aspect, the positioning accuracy is between about one micrometer (1 μm) and about ten micrometers (10 μm). In the third aspect, the positioning accuracy is generally less than one micrometer (1 μm). A discussion of each aspect now follows.

### 1. Positioning Accuracy Greater Than 10 μm

According to some embodiments, the method of forming a large-area nanoimprint mold master is configured to provide tile-positioning accuracy greater than about 10 μm. According to these embodiments, the wafer tiles or sub-master tiles may be cut to a reasonable precision. For example, a reasonable precision may be a precision that is equal to or greater than about 10 μm. Following cutting, the sub-master tiles may be laid down or placed on a rigid planar substrate. According to various embodiments, the rigid planar substrate may comprise, but is not limited to, a glass substrate, a ceramic substrate, or a metal substrate (e.g., a metal plate). Positioning of the sub-mater tiles on the rigid planar substrate may be guided by alignment pins or marks or pockets premade on the rigid planar substrate, for example.

The sub-master tiles may be bonded to the rigid planar substrate using a bonding material such as, but not limited to, a glue or other suitable adhesive material. The thickness may be controlled to achieve a flat and well-leveled tiling top surface, according to various embodiments. Further, any gaps between sub-master tiles may be filled. For example, the gaps may be filled using the bonding material or another gap-filling material.

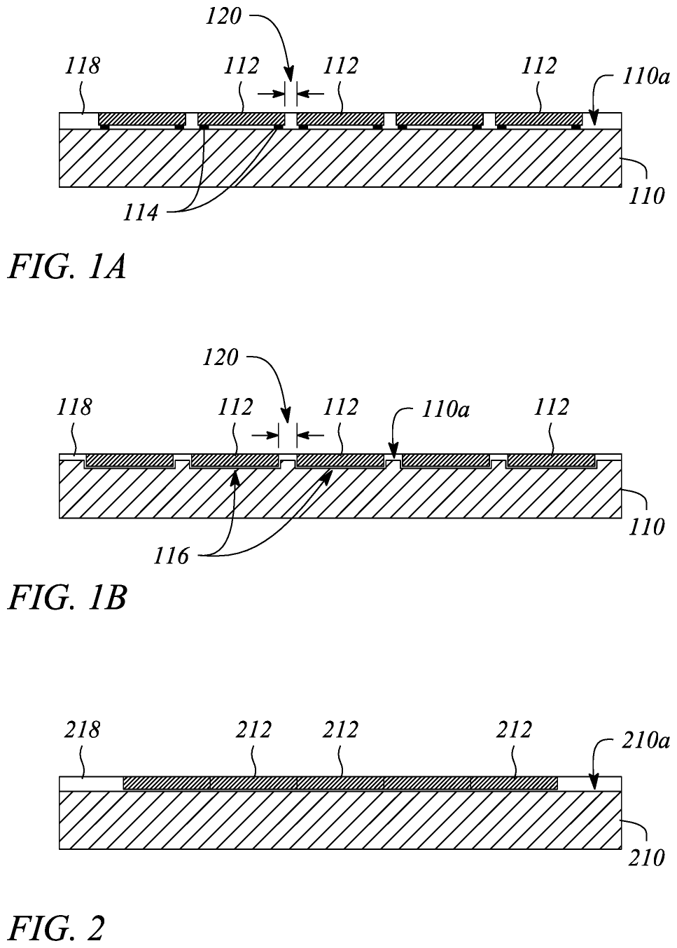

FIG. 1A illustrates a cross-sectional view of a large-area nanoimprint mold master 100 in an example, according to an embodiment consistent with the principles described herein. FIG. 1B illustrates a cross-sectional view of a large-area nanoimprint mold master 100 in an example, according to another embodiment consistent with the principles described herein. In particular, FIGS. 1A and 1B illustrate two alternative embodiments resulting from the first aspect of the method of forming a large-area nanoimprint mold master. As illustrated in FIG. 1A, a top surface 110a of a rigid planar substrate 110 supports a plurality of wafer tiles or equivalently a plurality of sub-master tiles 112. Further, guide pins or alignment marks 114 are provided on the rigid planar substrate 110, as illustrated. The guide pins or alignment mark 114 serve to align the sub-master tiles 112 on the rigid planar substrate 110 during placement.

In the alternative embodiment illustrated in FIG. 1B, pockets or recesses 116 are provided in the top surface 110a of the rigid planar substrate 110. The recesses 116 serve to align the sub-master tiles 112 on the rigid planar substrate 110, as illustrated in FIG. 1B. For example, when the sub-master tiles 112 are placed into the recesses 116, edges of the recesses 116 provide alignment of the sub-master tile 112.

In either embodiment illustrated in FIGS. 1A-1B, a bonding material 118 may be used to adhere the sub-master tiles 112 to the rigid planar substrate 110. Any of a variety of materials may be employed as the bonding material 118 including, but not limited to, a glue, a cement, or another adhesive. Further, the bonding material 118 may fill a gap 120 between the sub-master tiles 112, according to some embodiments. In some embodiments, a flowable gap-filling material such as, but not limited to, a glue, a UV-curable polymer, a thermal glue, etc., may be used to fill the gaps 120.

### 2. Positioning Accuracy Between 1 μm and 10 μm

According to some embodiments, the method of forming a large-area nanoimprint mold master is configured to provide tile-positioning accuracy between about 1 μm and about 10 μm. According to these embodiments, the wafer tiles or sub-master tiles are cut to according to a sub-micrometer precision, e.g., a precision of less than about one micrometer. Following cutting, the sub-master tiles may be laid down or positioned on a rigid planar substrate. Again, the rigid planar substrate may comprise, but is not limited to, a glass substrate, a ceramic substrate, or a metal substrate (e.g., a metal plate), according to various embodiments. Further, in these embodiments, the sub-master tiles are be placed side-by-side to each other with minimal gap in-between. In particular, the sub-mater tiles may be placed to provide contact between edges of adjacent sub-master tiles, i.e., adjacent sub-master tiles may be in direct contact with one another at respective adjacent or opposing edges thereof. Accordingly, the positioning accuracy of these embodiments is substantially determined by the tile cutting accuracy. In particular, gap between adjacent sub-master tiles may be zero or substantially zero in width, in some embodiments.

As described above, the sub-master tiles may be bonded to the substrate using a glue or other suitable adhesive material serving as a bonding material following placement on the rigid planar substrate. According to various embodiments, a thickness of the bonding material may be controlled to achieve a flat and well leveled to surface of the bonded sub-master tiles, i.e., a the tiling top surface. In some embodiments, a frame may be employed at an outside boundary of an array of the sub-master tiles on the rigid planar substrate, i.e., the tiled array. The frame may include alignment marks to be used in a downstream process, according to some embodiments.

FIG. 2 illustrates cross-sectional view of a large-area nanoimprint mold master 200 in an example, according to an embodiment consistent with the principles described herein. In particular, FIG. 2 illustrates an embodiment resulting from the second aspect of the method of forming the large-area nanoimprint mold master. FIG. 2 illustrates a substrate 210 configured to support a plurality of wafer tiles or equivalently a plurality of sub-master tiles 212. The sub-master tiles 212 abut each other, as illustrated. That is, there is substantially no gap between adjacent sub-master tiles 212 in FIG. 2.

According to various embodiments, a bonding material 218, such as, but not limited to, a glue, a cement, or another adhesive, may be used to adhere the sub-master tiles 212 to the rigid planar substrate 210. Any gaps that do exist may be filled with the bonding material 218 or other gap-filling material, such as the bonding material 118 described above, in some embodiments. The frame referred to above and alignment marks are not shown, by way of ease of illustration. In some embodiments, e.g., as with FIG. 1B, the sub-master tiles 212 may be assembled in a pocket or recess (not shown) in a top surface 210a of the rigid planar substrate 210.

3. Positioning Accuracy Less Than 1 μm

For tile positioning accuracy less than 1 μm, the wafer tiles or sub-master tiles may be cut to a sub-micrometer precision, and slightly smaller than the designed tile size. An alignment mark or pin or pocket array for tiling may then be patterned on a rigid planar substrate, such as a glass or ceramic or metal plate. The precisely cut sub-master tiles may be placed side-by-side, and then carefully adjusted using the alignment pins or marks or pockets premade on the substrate, leaving sub-micrometer gaps between sub-master tiles. Following placement, the tiles are bonded to the substrate by a glue or other adhesive material. The gaps between tiles are filled up precisely, e.g., utilizing surface tension between facets, to make the tiled surface seamless.

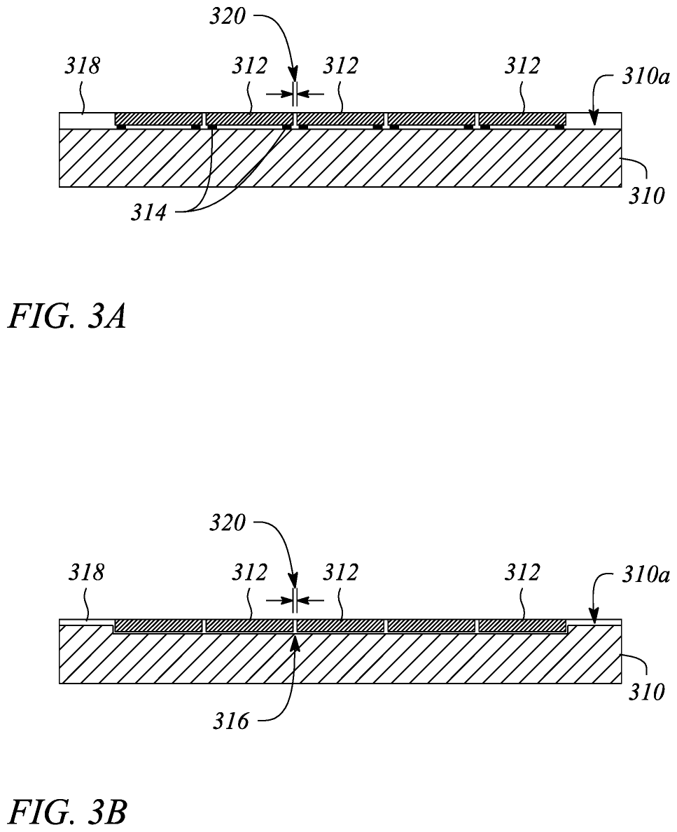

FIG. 3A illustrates a cross-sectional view of a large-area nanoimprint mold master 300 in an example, according to an embodiment consistent with the principles described herein. FIG. 3B illustrates a cross-sectional view of a large-area nanoimprint mold master 300 in an example, according to another embodiment consistent with the principles described herein. In particular, FIGS. 3A-3B illustrate two alternative embodiments resulting from the third aspect of the method of forming a large-area nanoimprint mold master. As illustrated in FIG. 3A, a top surface 310a of a rigid planar substrate 310 supports a plurality of wafer tiles or equivalently a plurality of sub-master tiles 312. Guide pins or alignment marks 314 serve to align the plurality of sub-master tiles 312 on the rigid planar substrate 310 during placement.

In the alternative embodiment illustrated in FIG. 3B, a pocket or recess 316 in the top surface 310a of the rigid planar substrate 310. The recess 316 serves to align the sub-master tiles 312 on the rigid planar substrate 310.

In either embodiment illustrated in FIGS. 3A-3B, a bonding material 318, such as, but not limited to, a glue, a cement, or another adhesive may be used to adhere the sub-master tiles 312 to the rigid planar substrate 310. Further, the bonding material 318 may fill a gap 320 between the sub-master tiles 312, according to some embodiments. In some embodiments, a flowable gap-filling material such as, but not limited to, a glue, a UV-curable polymer, a thermal glue, etc., may be used to fill the gaps 320.

### 4. Further Considerations

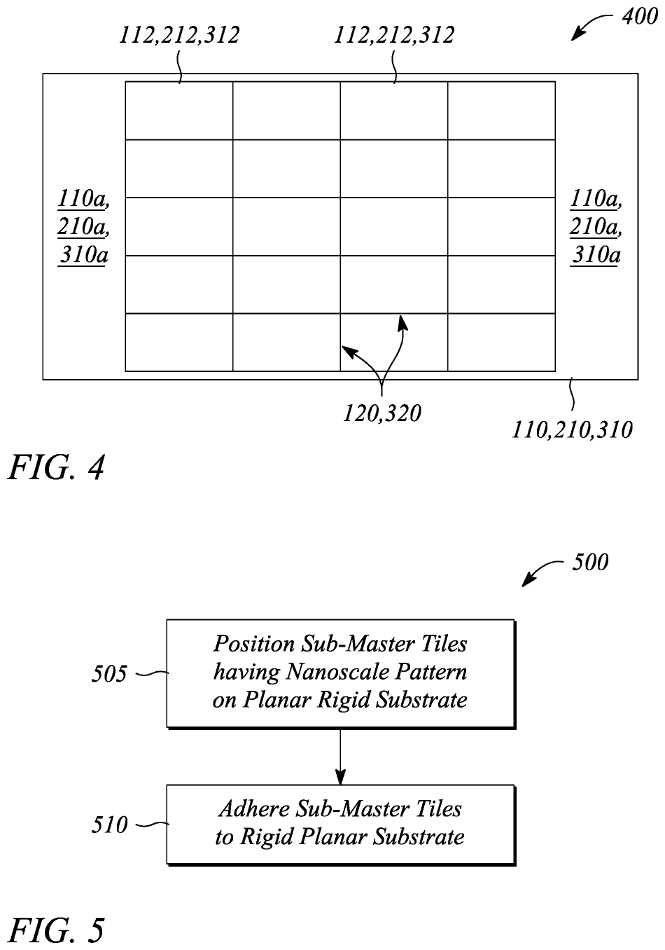

FIG. 4 illustrates a plan view of a large-area nanoimprint mold master 400 in an example, according to an embodiment consistent with the principles described herein. In particular, the large-area nanoimprint mold master 400 illustrated in FIG. 4 may represent any of the embodiments depicted in FIGS. 1A-1B, 2, and 3A-3B. As illustrated, a four-by-six (4×6) array of sub-master tiles 112, 212, 312 is depicted located on a rigid planar substrate 110, 210, 310. While FIG. 4 illustrates a 4×6 array, it is appreciated that essentially any two-dimensional array of sub-master tiles 112, 212, 312 may be placed on the rigid planar substrate 110, 210, 310 to form the large-area nanoimprint mold master 400 having dimensions of feet by feet (meters by meters), for example.

According to various embodiments, production stamps may be copied from the large-area nanoimprint mold master 400 and then used in production imprinting. Structure precision and consistency on production stamps are maintained as the production stamps are originated from the same high fidelity the large-area nanoimprint mold master 400.

In accordance with embodiments of principles described herein, a method of forming the tiled wafer master, also called a large-area nanoimprint mold master, is provided. FIG. 5 illustrates a flow chart of a method 500 of forming the large-area nanoimprint mold master, according to an embodiment consistent with the principles described herein. FIG. 5 illustrates a flow chart of a method 500 of forming a large-area nanoimprint mold master in an example, according to an embodiment consistent with the principles described herein. As illustrated in FIG. 5, the method 500 of forming the large-area nanoimprint mold master comprises positioning 505 a plurality of sub-master tiles on a rigid planar substrate. Each sub-master tile of the sub-master tile plurality has a nanoscale pattern and represents a subsection of the large-area nanoimprint mold master. In some embodiments, the sub-master tiles and rigid planar substrate may be substantially to the above-described sub-master tiles 112, 212, 312 and rigid planar substrate 110, 210, 310, respectively, of the large-area nanoimprint mold master 100, 200, 300, 400.

As indicated, each sub-master tile contains a part of the pattern of the large area nanoimprint master. The pattern on each sub-master tile is of nanoscale dimensions. Such a pattern is what provides the large area nanoimprint master with nanoscale features. Further, the rigid planar substrate may comprise any material suitable for supporting the sub-master tiles such as, but not limited to, glass, ceramic, metal, plastic, etc., so long as the substrate is both rigid and planar. As used herein, the terms ‘rigid’ and ‘planar’ retain their usual meaning, namely, ‘unable to bend or be forced out of shape; not flexible’ and ‘flat’, respectively. These terms are to be taken within the context of conventional manufacturing tolerances for fabricating substrates, such as for semiconductor functionality.

The method 500 further comprises adhering 510 the plurality of sub-master tiles to the rigid planar substrate. The adhering 510 may be performed with any convenient bonding material (e.g., bonding material 118, 218, 318) that binds the sub-master tiles to the rigid planar substrate sufficiently permanently to prevent their removal during the imprinting or replicating operation. Examples of suitable bonding material include, but are not limited to, UV-curable glues and thermal glues. There may or may not be gaps (e.g., gaps 120, 320) between sub-master tiles. Such gaps, if present, may be filled with the bonding material, according to some embodiments.

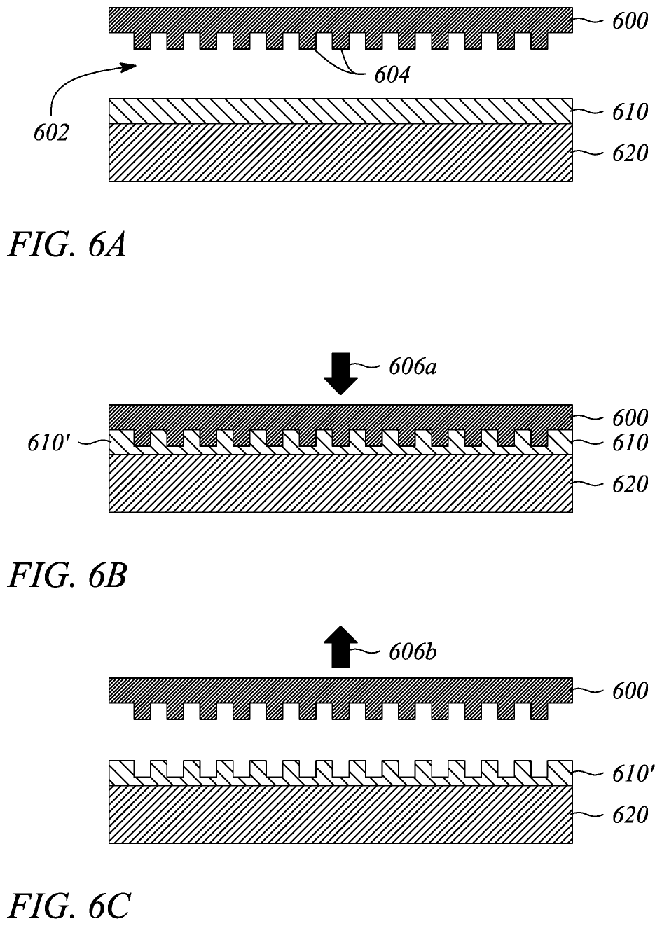

The positioning 505 determines a distance between a nanoscale feature of the nanoscale pattern on each sub-master tile of a pair of adjacent sub-master tiles. The distance may have microscale positioning tolerance. Nanoscale features 604 are depicted in FIGS. 6A-6C, discussed below.

In some embodiments, the positioning 505 comprises guiding the sub-master tiles into position on the rigid planar substrate using one of alignment pins and alignment marks. Examples of alignment marks 114 and 314 are illustrated in FIGS. 1B and 3B, respectively. The microscale positioning tolerance may be less than 100 μm.

In some embodiments, the rigid planar substrate comprises a plurality of surface recesses (e.g., recesses 116, 316) configured to accept the sub-master tiles. The positioning 505 comprises guiding the sub-master tiles into position on the rigid planar substrate by placing a sub-master tile in a recess of the surface recess plurality. In some embodiments, the surface recess is configured to hold a single sub-master tile in position; see, e.g., FIG. 1B. In such a case, the microscale positioning tolerance may be provided by the positioning being less than one hundred micrometers (100 μm).

In some embodiments, the positioning comprises abutting adjacent sub-master tiles against one another on the rigid planar substrate; see, e.g., FIG. 2. In such a case, a size of each of the sub-master tiles 112, 212, 312 may be controlled to provide the microscale positioning tolerance. In some embodiments, the size of the sub-master tile may be controlled to provide the microscale position tolerance of less than ten micrometers (10 μm).

In some embodiments, a size of each sub-master tile is controlled to create a sub-micrometer gap (e.g., gaps 120, 320) between adjacent sub-master tiles after positioning (in some embodiments, such as shown in FIG. 2, there may be no gap). This may be achieved by readjusting a position of sub-master tiles of the sub-master tile plurality to provide the microscale position tolerance of less than one micrometer (1 μm); see, e.g., FIG. 3A. In some embodiments, the rigid planar substrate further comprises one or more of a recess, alignment pins, and alignment marks used to facilitate the readjusting a position of the sub-master tiles. Also in some embodiments, the sub-micrometer gap may be filled to provide a smooth tiled surface of the large-area nanoimprint mold master 400. Filling of gaps may be achieved with the bonding material or other suitable gap-filling material.

In some embodiments, a layer of metal may be deposited on the large-area nanoimprint mold master to form a metal shim replica of the large-area nanoimprint mold master. For example, the metal layer may be deposited on the large-area nanoimprint mold master 100, 200, 300 described above. The metal shim replica may be used in imprinting a large-area nanoimprint pattern in a receiving surface.

In accordance with other embodiments of principles described herein, the large-area nanoimprint mold master may be used in a method of large-area nanoimprint lithography. FIG. 6A illustrates a cross-sectional view of using a large-area nanoimprint mold master to perform large-area nanoimprint lithography in an example, according to an embodiment consistent with the principles described herein. FIG. 6B illustrates another cross-sectional view of using the large-area nanoimprint mold master of FIG. 6A in an example, according to an embodiment consistent with the principles described herein. FIG. 6C illustrates another cross-sectional view of using the large-area nanoimprint mold master of FIG. 6A in an example, according to an embodiment consistent with the principles described herein. The large-area nanoimprint lithography illustrated in FIG. 6A-6C is provided for illustrative purposes and not by way of limitation. In particular, large-area nanoimprint lithography using the large-area nanoimprint mold master may be performed in substantially different ways without departing from the scope described herein.

As illustrated in FIG. 6A, a sub-master tile 600 is depicted, having a nanoscale pattern 602. According to some embodiments, the sub-master tile 600 may be substantially simile to any of the sub-master tiles 112, 212, 312 described above. The nanoscale pattern 602 comprises nanoscale features 604 having one or both of nanoscale dimensions and nanoscale spacings. For clarity, the rigid planar substrate 110, 210, 310 supporting sub-master tile 112, 212, 312, respectively, has been omitted from FIGS. 6A-6C. It will be appreciated, however, that in practice, a rigid, planar substrate supports the sub-master tile 600.

FIG. 6A also illustrates a polymer 610 or a polymerizable material disposed on a substrate 620. The polymer 610 is one that may be heat-curable or UV-curable, for example. The substrate 620 may comprise any material capable of supporting the polymer 610 during the processing.

FIG. 6B illustrates the sub-master tile 600 being brought into contact with the polymer 610, as depicted by the directional arrow 606a. While the sub-master tile 600 and the polymer 610 are pressed together, the polymer 610 is hardened to provide a cured polymer 610′. According to various embodiments, the cured polymer 610′ may be provided by thermo-polymerization where the polymer 610 is a thermoplastic polymer, employing heat, or by photo-polymerization where the polymerizable material is a photoresist, employing light. The particular polymer 610 or polymerizable material will dictate the temperature range of heat or the wavelength range of light to be employed in the curing process.

As illustrated in FIG. 6C, the sub-master tile 600 may then be separated from the cured polymer 610′, as shown by the directional arrow 606b. The negative of the nanoscale pattern 602 of the sub-master tile 600 is accordingly transferred to the cured polymer 610′. The cured polymer 610′ is now ready for use in stamping out copies of the original nanoscale pattern 602. To aid in the separation, the surface of the sub-master tile 600 may first be coated with a release agent prior to the pressing together 606a.

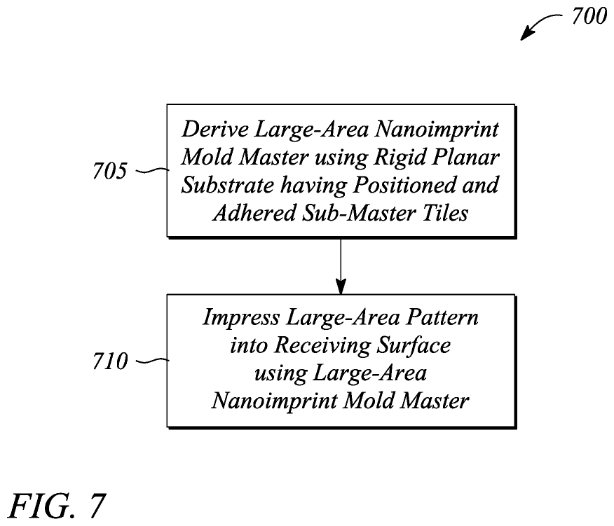

FIG. 7 illustrates a flow chart of a method 700 of large-area nanoimprint lithography, according to an embodiment consistent with the principles described herein. As illustrated in FIG. 7, the method 700 of large-area nanoimprint lithography comprises deriving 705 a large-area nanoimprint mold using a large-area nanoimprint mold master having a rigid planar substrate. In some embodiments, the large-area nanoimprint mold master may be substantially similar to the large-area nanoimprint mold master 100, 200, 300, 400 described above. The large-area nanoimprint mold master may comprise a plurality of sub-master tiles adhered to a surface of a rigid planar substrate. The rigid planar substrate may be substantially similar to the rigid planar substrate 110, 210, 310 and the a plurality of sub-master tiles 112, 212, 312 positioned on and adhered to a top surface 110a, 210a, 310a of the rigid planar substrate, in some embodiments. Sub-master tiles of the sub-master tile plurality have a nanoscale pattern (e.g., nanoscale pattern 602) and are positioned to provide a microscale positioning tolerance between a nanoscale feature of the nanoscale pattern on each sub-master tile of a pair of adjacent sub-master tiles.

The method 700 further comprises impressing 710 into a receiving surface a large-area pattern using the large-area nanoimprint mold master. The large-area pattern 602 has the nanoscale features 604 of the sub-master tile plurality of the large-area nanoimprint mold master. In some embodiments, a stamp copy may be provided from the large-area nanoimprint mold master by making an imprint into a soft flexible film and then apply a surface treatment or coating before being used in imprint production to allow easy release from the imprint resin material. This approach may minimize a number of intermediate steps to transfer the pattern, and further may extend a lifetime of the large-area nanoimprint mold master. In other embodiments, a nickel shim replica of the large-area nanoimprint mold master may be formed using electro-plating. The nickel shim replica generally has good surface release properties from the imprint resin, is less sensitive to thermal effects, and can be cleaned and reused to extend its lifetime.

In some embodiments, deriving 705 comprises one of using the large-area nanoimprint mold master as the large-area nanoimprint mold and depositing a metal layer on the large-area nanoimprint mold master to form a metal shim replica of the large-area nanoimprint mold master. The metal shim replica is to be used as the large-area nanoimprint mold. In some embodiments, a receiving surface (e.g., receiving surface 610) comprises poly(methyl methacrylate) or a coating of poly(methyl methacrylate) on a substrate 620. In some embodiments, the receiving surface is a surface of a light guide of a multiview backlight and the large-area pattern comprises a plurality of diffraction gratings used to diffract light out of the light guide as a plurality of directional light beams that form a light field of the multiview backlight. In this case, the nanoscale patterns 602 are the diffraction gratings formed on the surface of the multiview backlight.

Thus, there have been described examples of a method of forming a large-area nanoimprint mold master, examples of the large-area nanoimprint mold master, and examples of a method of large-area nanoimprint lithography. It should be understood that the above-described examples are merely illustrative of some of the many specific examples that represent the principles described herein. Clearly, those skilled in the art can readily devise numerous other arrangements without departing from the scope as defined by the following claims.

What is claimed is:

1. A method of forming a large-area nanoimprint mold master, the method comprising:
positioning a plurality of sub-master tiles on a rigid planar substrate, each sub-master tile of the sub-master tile plurality having a nanoscale pattern and representing a subsection of the large-area nanoimprint mold master; and
adhering the plurality of sub-master tiles to the rigid planar substrate,
wherein the positioning determines a distance between a nanoscale feature of the nanoscale pattern on each sub-master tile of a pair of adjacent sub-master tiles, the distance having microscale positioning tolerance.

2. The method of forming a large-area nanoimprint mold master of claim 1, wherein the positioning comprises is guiding the sub-master tiles into position on the rigid planar substrate using one of alignment pins and alignment marks, the microscale positioning tolerance being less than one hundred micrometers (100 μm).

3. The method of forming a large-area nanoimprint mold master of claim 1, wherein the rigid planar substrate comprises a plurality of surface recesses configured to accept the sub-master tiles, the positioning comprising guiding the sub-master tiles into position on the rigid planar substrate by placing a sub-master tile in a recess of the recess plurality.

4. The method of forming a large-area nanoimprint mold master of claim 3, wherein the recess is configured to hold a single sub-master tile in position, the microscale positioning tolerance provided by the positioning being less than one hundred micrometers (100 μm).

5. The method of forming a large-area nanoimprint mold master of claim 1, wherein the positioning comprises abutting adjacent sub-master tiles against one another on the rigid planar substrate, a size of each of the sub-master tiles being controlled to provide the microscale positioning tolerance.

6. The method of forming a large-area nanoimprint mold master of claim 5, wherein the size of the sub-master tile is controlled to provide the microscale position tolerance of less than ten micrometers (10 μm).

7. The method of forming a large-area nanoimprint mold master of claim 1, wherein a size of each sub-master tile is controlled to create a sub-micrometer gap between adjacent sub-master tiles after positioning, the method further comprising readjusting a position of sub-master tiles of the sub-master tile plurality to provide the microscale position tolerance of less than one micrometer (1 μm).

8. The method of forming a large-area nanoimprint mold master of claim 7, wherein the rigid planar substrate further comprises one or more of a recess, alignment pins, and alignment marks used to facilitate the readjusting a position of the sub-master tiles.

9. The method of forming a large-area nanoimprint mold master of claim 7, the method further comprising filling the sub-micrometer gap to provide a smooth tiled surface of the large-area nanoimprint mold master.

10. The method of forming a large-area nanoimprint mold master of claim 1, further comprising depositing a layer of a metal layer on the large-area nanoimprint mold master to form a metal shim replica of the large-area nanoimprint mold master, the metal shim replica to be used in imprinting of a large-area nanoimprint pattern in a receiving surface.

11. A large-area nanoimprint mold master comprising:
a rigid planar substrate; and
a plurality of sub-master tiles positioned on and adhered to a surface of the rigid planar substrate, sub-master tiles of the sub-master tile plurality having a nanoscale pattern and being positioned to provide a microscale positioning tolerance between a nanoscale feature of the nanoscale pattern on each sub-master tile of a pair of adjacent sub-master tiles,
wherein the sub-master tiles of the sub-master tile plurality represent subsections of the large-area nanoimprint mold master.

12. The large-area nanoimprint mold master of claim 11, wherein in the rigid planar substrate comprises one or both of alignment pins and alignment marks configured as a position reference of the sub-master tiles on the rigid planar substrate.

13. The large-area nanoimprint mold master of claim 11, wherein the rigid planar substrate comprises a surface recess in the rigid planar substrate surface, the surface recess being configured to accept and position a sub-master tile of the sub-master tile plurality.

14. The large-area nanoimprint mold master of claim 11, wherein adjacent sub-master tiles of the sub-master tile plurality abut one another on the rigid planar substrate surface, a size of each of the sub-master tiles being controlled to tolerance of less than ten micrometers (10 μm) to provide the microscale positioning tolerance.

15. The large-area nanoimprint mold master of claim 11, further comprising a sub-micrometer gap between adjacent sub-master tiles of the sub-master tile plurality, the sub-micrometer gap being configured to provide the microscale position tolerance of less than 1 micrometer.

16. The large-area nanoimprint mold master of claim 11, further comprising a gap-filling material in a gap between adjacent sub-master tiles, the gap-filling material being configured to provide the large-area nanoimprint mold master having a smooth tiled surface.

17. A method of large-area nanoimprint lithography, the method comprising:
deriving a large-area nanoimprint mold using a large-area nanoimprint mold master having a rigid planar substrate and a plurality of sub-master tiles positioned on and adhered to a surface of the rigid planar substrate, sub-master tiles of the sub-master tile plurality having a nanoscale pattern and being positioned to provide a microscale positioning tolerance between a nanoscale feature of the nanoscale pattern on each sub-master tile of a pair of adjacent sub-master tiles; and
impressing into a receiving surface a large-area pattern using the large-area nanoimprint mold, the large-area pattern having the nanoscale patterns of the sub-master tile plurality of the large-area nanoimprint mold master.

18. The method of large-area nanoimprint lithography of claim 17, wherein deriving comprises one of using the large-area nanoimprint mold master as the large-area nanoimprint mold and depositing a metal layer on the large-area nanoimprint mold master to form a metal shim replica of the large-area nanoimprint mold master, the metal shim replica to be used as the large-area nanoimprint mold.

19. The method of large-area nanoimprint lithography claim 17, wherein the receiving surface comprises poly(methyl methacrylate) or a coating of poly(methyl methacrylate) on substrate.

20. The method of large-area nanoimprint lithography of claim 17, wherein the receiving surface is a surface of a light guide of a multiview backlight and the large-area pattern comprises a plurality of diffraction gratings used to diffract light out of the light guide as a plurality of directional light beams that form a light field of the multiview backlight.
